(19) United States
(12) Patent Application Publication
(10) Pub. No.: US 2025/0336602 A1
(43) Pub. Date: Oct. 30, 2025

(54) INTEGRATED HEAT DISSIPATION DEVICE FOR ANNULAR CAPACITOR

(71) Applicant: Shanghai University of Engineering Science, Shanghai (CN)

(72) Inventors: Hui GUO, Shanghai (CN); Yi WANG, Shanghai (CN); Yansong WANG, Shanghai (CN); Tao YUAN, Shanghai (CN); Wei SHI, Shanghai (CN); Dingyu HU, Shanghai (CN); Shuai ZHANG, Shanghai (CN); Pei SUN, Shanghai (CN); Linhao HUANG, Shanghai (CN); Bin CHANG, Shanghai (CN)

(21) Appl. No.: 19/262,531

(22) Filed: Jul. 8, 2025

Related U.S. Application Data
(63) Continuation of application No. PCT/CN2024/144175, filed on Dec. 31, 2024.

(30) Foreign Application Priority Data
Jan. 23, 2024 (CN) 202410091759.9

(51) Int. Cl. H01G 2/08; H01G 2/10; H05K 7/20

(52) U.S. Cl. CPC H01G 2/08; H01G 2/106; H05K 7/20272; H05K 7/20927

(57) ABSTRACT

An integrated heat dissipation device for an annular capacitor is provided, including: an accommodating cavity with an annular structure formed inside a housing; a core assembly arranged within the accommodating cavity, and an accommodating space exists between the core assembly and the housing; a first heat dissipation loop arranged within the accommodating space, and filled with a coolant; a second heat dissipation loop arranged outside the housing, and configured to cooperate with the first heat dissipation loop to respectively exchange heat with opposite sides of the core assembly; and flow distribution mechanisms being respectively in communication with the first heat dissipation loop and the second heat dissipation loop.

### CROSS-REFERENCE TO RELATED APPLICATIONS

This application is a continuation of International Patent Application No. PCT/CN2024/144175, filed Dec. 31, 2024 and claims priority of Chinese Patent Application No. 202410091759.9, filed on Jan. 23, 2024. The entire contents of International Patent Application No. PCT/CN2024/144175 and Chinese Patent Application No. 202410091759.9 are incorporated herein by reference.

### TECHNICAL FIELD

The present disclosure belongs to the technical field of capacitor heat dissipation, and particularly relates to an integrated heat dissipation device for an annular capacitor.

### BACKGROUND

At present, new energy vehicles have become the inevitable path for the sustainable development of the automotive industry, and drive motor controllers are evolving toward higher power density, higher efficiency, and miniaturization. When capacitors operate in drive motor controllers, the power modules also work at high frequencies and high power. Capacitors may achieve rapid charging and discharging, thereby providing smooth filtering, and circuit protection functions. However, due to the capacitance characteristics of capacitors, the current inside capacitors are not entirely smooth but exhibits periodic variations over time, resulting in ripple current. Ripple current is the main cause of heat generation in capacitors. When capacitors operate at high temperatures, their service life and performance are adversely affected. Currently, to meet the demands of drive motor controllers with higher power density and operating frequencies, designing heat dissipation devices to enhance the high-temperature resistance and ripple current tolerance of capacitors has become an urgent issue to address.

Existing heat dissipation devices for capacitors are often placed at the bottom or top of the capacitor, resulting in inefficient heat dissipation. Additionally, designing heat dissipation devices at the bottom or top increases the volume of the capacitor and the drive motor controller, going against the development direction of drive motor controllers towards high power density, high efficiency, and miniaturization. To address this issue, the present disclosure provides an integrated heat dissipation device for an annular capacitor to solve the aforementioned problems.

### SUMMARY

An objective of the present disclosure is to provide an integrated heat dissipation device for an annular capacitor to address the aforementioned issues, improving the heat dissipation effect and achieving efficient heat dissipation for annular capacitors on the basis of reducing the volume proportion of the heat dissipation device.

To achieve this objective, the present disclosure provides the following solution: an integrated heat dissipation device for an annular capacitor, including:
a housing, where an accommodating cavity with an annular structure is formed inside the housing;
a core assembly arranged within the accommodating cavity, where an accommodating space is formed between the core assembly and an inner end surface of the housing;
a first heat dissipation loop arranged within the accommodating space, where the first heat dissipation loop is filled with a coolant;
a second heat dissipation loop arranged outside the housing, where the second heat dissipation loop is configured to cooperate with the first heat dissipation loop to respectively exchange heat with on opposite sides of the core assembly; and
a pair of flow distribution mechanisms arranged on the housing, and configured to exchange heat with an inner side of the housing; the pair of flow distribution mechanisms are in communication with the first heat dissipation loop and the second heat dissipation loop, and the pair of flow distribution mechanisms are configured to extend in a direction away from the housing and respectively form an inlet channel and an outlet channel for circulating the coolant;
where the first heat dissipation loop and the second heat dissipation loop respectively form circulation paths in at least two directions from an inlet end to an outlet end through the pair of flow distribution mechanisms.

In some embodiments, the pair of flow distribution mechanisms are configured to form multiple circumferentially distributed heat dissipation ends corresponding to a side wall surface of the accommodating cavity; and the pair of flow distribution mechanisms are in communication with opposite sides of the first heat dissipation loop and the second heat dissipation loop, and one of the pair of flow distribution mechanisms is used to introduce the coolant, another of the flow distribution mechanisms is used to discharge the coolant.

In some embodiments, the pair of flow distribution mechanisms includes:
multiple first heat dissipation channels, where the multiple first heat dissipation channels are uniformly distributed on an inner wall surface of an inner ring of the accommodating cavity; ends of the first heat dissipation channels extend in a direction away from the housing for introducing and discharging the coolant respectively, other ends of the first heat dissipation channels are in communication with the first heat dissipation loop; and throttling channels are integrally formed on the first heat dissipation channels, and the throttling channels are configured to be in communication with the second heat dissipation loop.

In some embodiments, one of the pair of flow distribution mechanisms is configured to cover half of the inner wall surface of the inner ring of the accommodating cavity.

In some embodiments, the first heat dissipation loop includes:
multiple second heat dissipation channels, arranged within the accommodating space, where the multiple second heat dissipation channels cooperate to form a multi-layer annular structure about a same center, the center is located on a same axis as a center of a circle of the housing; and the multiple second heat dissipation channels are respectively in communication with each other through a pair of connecting channels, and the pair of connecting channels are configured to respectively be in communication with the first heat dissipation channels on the pair of flow distribution mechanisms.

In some embodiments, the second heat dissipation loop includes:
a third heat dissipation channel arranged on a side outside the housing away from the first heat dissipation loop, where a groove is provided on a side of the third heat dissipation channel close to the housing, and the groove cooperates with an outer wall of the housing to form a sealed cavity; and the first heat dissipation channels located on the pair of flow distribution mechanisms are respectively in communication with opposite sides of the groove.

In some embodiments, embedded slots are oppositely provided on an inner side wall of the groove, and each of the throttling channels is clamped with a corresponding one of the embedded slots.

In some embodiments, the housing includes:
an outer shell and an inner shell fixedly connected to the outer shell, where two ends of the inner shell are through ends, and the multiple first heat dissipation channels penetrate the inner shell and contact with an inner wall surface of the inner shell; the accommodating cavity is formed between the outer shell and the inner shell, where the accommodating cavity is filled with a filling material, a height difference is formed between a top of the filling material and a top of the outer shell, and the first heat dissipation loop is configured to be arranged in the height difference to contact with the filling material.

In some embodiments, the core assembly includes:
multiple capacitor cores and a core insulation layer, where the capacitor cores are regularly arranged within the accommodating cavity, and the core insulation layer covers a top of the capacitor cores; and a busbar is arranged on one side of the core insulation layer, the busbar is connected to the capacitor cores, and the busbar extends out of the housing in a direction away from the capacitor cores.

Compared with the relevant art, the present disclosure has the following advantages and technical effects.

In the present disclosure, by arranging the accommodating cavity with the annular structure inside the housing and placing the core assembly within the accommodating cavity with the accommodating space forming between the core assembly and the accommodating cavity, and arranging the first heat dissipation loop within the accommodating space, the volume increase caused by the installation of the first heat dissipation loop is minimized relative to the capacitor structure, and thereby minimizing the additional volume occupied by the heat dissipation device. Additionally, the first heat dissipation loop and the second heat dissipation loop respectively form a heat dissipation effect on opposite sides of the core assembly. Further, the flow distribution mechanisms perform heat exchange on the other side of the housing away from the first heat dissipation loop and the second heat dissipation loop, effectively improving dissipation effect. In addition, the flow distribution mechanisms also realize the coolant circulation to the first heat dissipation loop and the second heat dissipation loop through the arranged inlet and outlet channels, thereby achieving high-efficiency heat dissipation for the entire capacitor structure.

### BRIEF DESCRIPTION OF THE DRAWINGS

In order to explain the embodiments of the present disclosure or the technical solution in the prior art more clearly, the drawings needed in the embodiments will be briefly introduced below. Apparently, the drawings in the following description are only some embodiments of the present disclosure. For one of ordinary skill in the art, other drawings may be obtained according to these drawings without creative effort:

FIG. 1 is an exploded view of an overall device structure.

FIG. 2 is a schematic structural view of a housing and a core assembly filled with a filling material.

FIG. 3 is a structural view of a busbar, the filling material, and the housing in a disassembled state.

FIG. 4 is a connection diagram of a first heat dissipation loop and a second heat dissipation loop.

FIG. 5 is a positional relationship diagram of flow distribution mechanisms and an inner shell.

FIG. 6 is a positional relationship diagram of throttling channels and first heat dissipation channels.

FIG. 7 is a layout diagram of an integrated capacitor heat dissipation device inside a motor controller.

### DETAILED DESCRIPTION OF THE EMBODIMENTS

In the following, the technical solutions in the embodiments of the present disclosure will be clearly and completely described with reference to the attached drawings. Apparently, the described embodiments are only a part of the embodiments of the present disclosure, but not all the embodiments. Based on the embodiments in the present disclosure, all other embodiments obtained by one of ordinary skill in the art without creative effort belong to the protection scope of the present disclosure.

In order to make the above objects, features and advantages of the present disclosure more obvious and easier to understand, the present disclosure will be further described in detail with the attached drawings and specific embodiments.

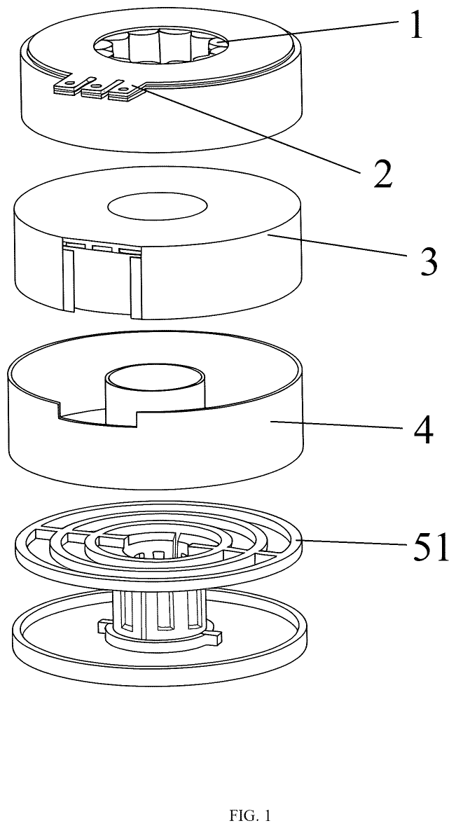

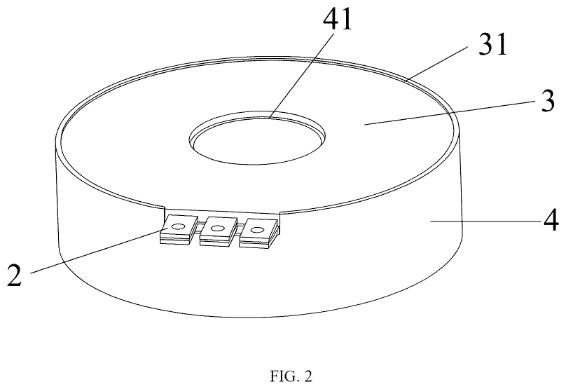

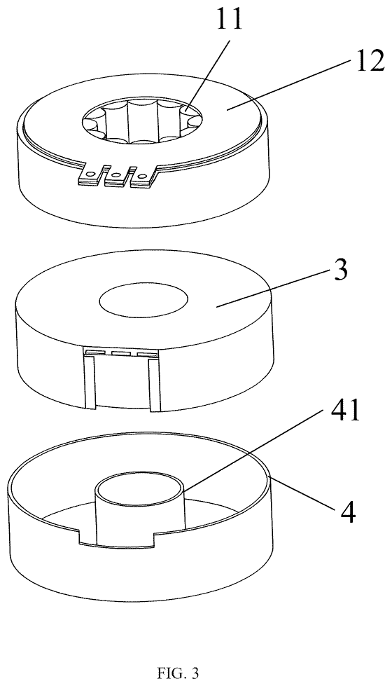

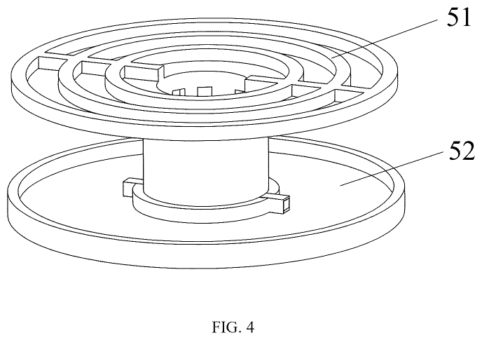

With reference to FIG. 1 to FIG. 7, an integrated heat dissipation device for an annular capacitor is provided, which includes: a housing, a core assembly 1, a first heat dissipation loop 51, a second heat dissipation loop 52, and a pair of flow distribution mechanisms.

An accommodating cavity with an annular structure is formed inside the housing.

The core assembly 1 is arranged within the accommodating cavity, an accommodating space exists between the core assembly 1 and an inner end surface of the housing;

The first heat dissipation loop 51 is arranged within the accommodating space, the first heat dissipation loop 51 is filled with a coolant.

The second heat dissipation loop 52 is arranged outside the housing, the second heat dissipation loop 52 is configured to cooperate with the first heat dissipation loop 51 to respectively generate heat exchange on opposite sides of the core assembly 1.

The pair of flow distribution mechanisms are arranged on the housing, and configured to generate heat exchange on an inner side wall of the housing. The flow distribution mechanisms are in communication with the first heat dissipation loop 51 and the second heat dissipation loop 52, and the flow distribution mechanisms are configured to extend in a direction away from the housing and respectively form an inlet channel and an outlet channel for circulating the coolant.

The first heat dissipation loop 51 and the second heat dissipation loop 52 form at least two circulation paths in different directions from an inlet end to an outlet end through the pair of flow distribution mechanisms.

In the present disclosure, the accommodating cavity with the annular structure is formed inside the housing, the core assembly 1 is arranged within the accommodating cavity, and the accommodating space is formed between the core assembly 1 and the accommodating cavity, the first heat dissipation loop 51 is arranged within the accommodating space, thereby effectively mitigating the volume increase caused by the addition of the first heat dissipation loop 51 relative to the capacitor structure, and minimizing the additional volume occupied by the heat dissipation device. Additionally, the first heat dissipation loop 51 and the second heat dissipation loop 52 respectively form heat dissipation effect on opposite sides (top and bottom ends) of the core assembly 1, while the flow distribution mechanisms perform heat exchange on the other side (side surface) of the housing away from the first heat dissipation loop 51 and the second heat dissipation loop 52, thereby forming heat dissipation on at least three sides and significantly improving heat dissipation efficiency. Furthermore, the inlet and outlet channels formed by the pair of flow distribution mechanisms are in fluid communication with the first heat dissipation loop 51 and the second heat dissipation loop 52, forming coolant circulation paths in at least two different directions from the inlet end to the outlet end at the connection points of the first heat dissipation loop 51 and the second heat dissipation loop 52, accelerating the coolant flow rate and promoting heat dissipation, thereby achieving high-efficiency heat dissipation for the entire capacitor structure.

In an embodiment, the pair of flow distribution mechanisms are configured to form multiple circumferentially distributed heat dissipation ends corresponding to the side wall surface of the accommodating cavity. Two ends of the pair of flow distribution mechanisms are respectively in communication with opposite sides of the first heat dissipation loop 51 and the second heat dissipation loop 52, when one of the pair of flow distribution mechanisms is used to introduce the coolant, the other is used to discharge the coolant.

By configuring the flow distribution mechanisms as a pair of cooperating mechanisms, the two ends of the flow distribution mechanisms are in communication with opposite sides of the first heat dissipation loop 51 and the second heat dissipation loop 52, respectively, enabling the pair of cooperating mechanisms to respectively introduce the coolant and discharge the coolant to circulate and deliver the coolant. It is understandable that the first heat dissipation loop 51 and the second heat dissipation loop 52 in communication with the pair of flow distribution mechanisms respectively are through-passage structures, thereby realizing the circulation and delivery of the coolant through the flow distribution mechanisms in the first heat dissipation loop 51 and the second heat dissipation loop 52, and ensuring the heat dissipation effect.

In an embodiment, the flow distribution mechanisms include:
multiple first heat dissipation channels 504, and the multiple first heat dissipation channels 504 are uniformly distributed on the inner wall surface of the inner ring of the accommodating cavity, two of ends the first heat dissipation channels 504 extend in a direction away from the housing for introducing and discharging the coolant, while the other ends of the first heat dissipation channels are in fluid communication with the first heat dissipation loop 51. Throttling channels 507 are integrally formed on the first heat dissipation channels 504 and configured to be in fluid communication with the second heat dissipation loop 52, introducing the coolant exceeding the flow rate in the first heat dissipation loop 51 into the third heat dissipation channel 502.

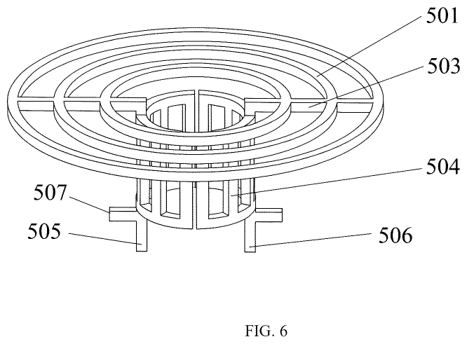

In this technical solution, converging channels (each indicated as an annular structure in FIG. 6) is additionally provided on the flow distribution mechanisms. The two ends of the multiple first heat dissipation channels 504 are fluidly communicated through the converging channels respectively. The first heat dissipation channel 504, located in the middle, of one flow distribution mechanisms extends out of the housing, forming a liquid inlet 505 for introducing the coolant. The first heat dissipation channel 504 of the other flow distribution mechanism extends out of the housing to form a liquid outlet 506 for discharging the coolant. The pair of flow distribution mechanisms cooperate to circulate and deliver the coolant. Moreover, any two of the first heat dissipation channels 504 on the pair of flow distribution mechanisms are interconnected only through the first heat dissipation loop 51 and the second heat dissipation loop 52, so that the first heat dissipation channels 504 circulate and deliver coolant to ensure its heat dissipation effect, while simultaneously forming coolant circulation effect on the first heat dissipation loop 51 and the second heat dissipation loop 52, enhancing heat dissipation effect and effectively accelerating the coolant circulation speed, improving the heat dissipation efficiency.

Additionally, the first heat dissipation channels 504 are provided with the throttling channels 507, and are in fluid communication with the second heat dissipation loop 52 through the throttling channels 507. Since the throttling channels 507 are in communication with the second heat dissipation loop 52, while enabling coolant circulation in the second heat dissipation loop 52, the throttling channels 507 introduce coolant exceeding the flow limit in the first heat dissipation loop 51 into the second heat dissipation loop 52, and the second heat dissipation loop 52 also provides a pressure relief and buffering function for the first heat dissipation loop 51. With the second heat dissipation loop 52 arranged outside the housing and the first heat dissipation loop 51 arranged within the accommodating space, the structural stability of the first heat dissipation loop 51 is ensured, avoiding structural damage and leakage caused by excessive coolant pressure, improving the heat dissipation effect of the capacitor, and enhancing the practicality of the heat dissipation device.

In an embodiment, any one of the pair of flow distribution mechanisms is configured to cover half of the inner wall surface of the inner ring of the accommodating cavity.

By covering half of the inner wall surface of the inner ring of the accommodating cavity with any one of the flow distribution mechanisms, the pair of flow distribution mechanisms cooperatively cover the side wall of the accommodating cavity through the multiple first heat dissipation channels 504. With the flow distribution mechanisms in contact with the housing, heat dissipation effect on the capacitor is further enhanced.

In an embodiment, the first heat dissipation loop 51 includes:
multiple second heat dissipation channels 501 arranged within the accommodating space, and the multiple second heat dissipation channels 501 cooperate to form a circumferential outward annular structure along the same center of the circle, with the center is located on the same axis as the center of the circle of the housing. The multiple second heat dissipation channels 501 are in fluid communication with each other through a pair of connecting channels 503, and the pair of connecting channels 503 are configured to be respectively in communication with the converging channels of the pair of flow distribution mechanisms.

Multiple annular second heat dissipation channels 501 are circumferentially and sequentially arranged outward along the same center of the circle, forming an annular structure matching the end surface of the accommodating cavity, thus covering the top of the core assembly 1, expanding the contact area with the core assembly 1, and enhancing the heat dissipation effect on the core assembly 1. The opposite sides of the multiple annular second heat dissipation channels 501 are respectively in communication with the two first heat dissipation channels 504 of the pair of flow distribution mechanisms through the pair of connecting channels 503, forming a coolant circulation loop in the multiple second heat dissipation channels 501 along the direction of one flow distribution mechanism to the other flow distribution mechanism. It is understandable that the connecting channels 503 on the opposite sides are symmetrically arranged to ensure the heat dissipation effect generated on the multiple second heat dissipation channels 501 during coolant circulation.

In an embodiment, the second heat dissipation loop 52 includes:
a third heat dissipation channel 502 arranged on a side outside the housing away from the first heat dissipation loop 51, and a groove is provided on a side of the third heat dissipation channel 502 close to the housing, and the groove cooperates with the outer wall of the housing to form a sealed cavity. The first heat dissipation channels 504 located on the pair of flow distribution mechanisms are respectively communicated with the opposite sides of the groove.

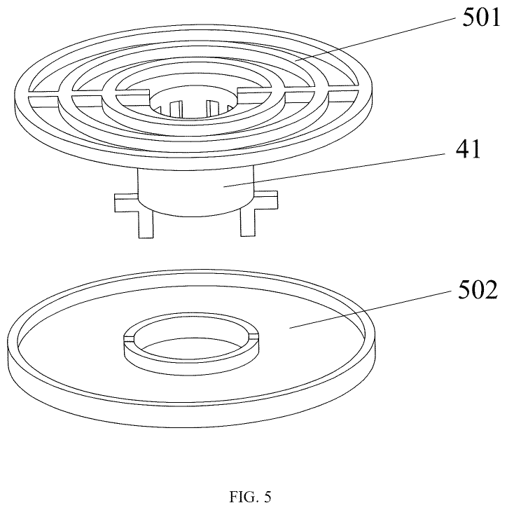

With reference to FIG. 5, the third heat dissipation channel 502 is a groove structure. The groove is buckled on the outer wall surface of the housing to form a sealed cavity. The third heat dissipation channel 502 and the first heat dissipation loop 51 are arranged on opposite sides of the housing, so that the second heat dissipation channels 501 and the third heat dissipation channel 502 respectively form heat dissipation effects on the top and bottom of the core assembly 1, thereby improving the heat dissipation effect for the capacitor.

In this technical solution, the second heat dissipation channels 501 and the first heat dissipation channels 504 are both channel structures with rectangular inner sections, and the channel width is 2 millimeters (mm) and the height is 0.5 mm. The inner walls of the rectangular flow channels are provided with streamlined chamfers to facilitate circulating flow of the coolant. The following formula is used:

$${R}_{e} = \frac{{ρ}_{w} v d}{μ} ,$$

where Rₑ is the Reynolds number, ρ_{w} (kilogram per cubic meter (kg/m³)) is the fluid density, v (meter per second (m/s)) is the fluid velocity, d (meter (m)) is the characteristic dimension, i.e., vector length, and μ (kilogram per meter per second (kg/m·s)) is the fluid viscosity. The coolant is liquid water, with a maximum flow velocity set to 0.6 m/s, corresponding to a Reynolds number below 2300, ensuring laminar flow effect of the coolant in the second heat dissipation channels 501 and thereby ensuring heat dissipation.

Additionally, diversion walls (not shown in the figures) are provided at the positions of the throttling channels 507 on the first heat dissipation channels 504 to facilitate coolant flow into the groove and enable heat dissipation in the third heat dissipation channel 502.

In an embodiment, embedded slots are oppositely provided on the opposite sides of the inner side wall of the groove, and the end of each of the throttling channels 507 extending into the third heat dissipation channel 502 is clamped with a respective embedded slot.

By providing the embedded slots on the inner wall of the groove, the throttling channels 507 on the flow distribution mechanisms are clamped and fixed in the embedded slots respectively. The multiple second heat dissipation channels 501 are arranged between the top of the core assembly 1 and the inner wall surface of the housing, while the third heat dissipation channel 502 is fixed to the bottom of the housing through the throttling channels 507 and embedded slots, ensuring stable integration with the capacitor structure and facilitating installation and disassembly of the entire heat dissipation device.

In an embodiment, the housing includes:
an outer shell 4 and an inner shell 41 fixedly connected to the outer shell 4. Two ends of the inner shell 41 are through ends, and the multiple first heat dissipation channels 504 penetrate the inner shell 41 and contact with the inner wall surface of the inner shell 41. The accommodating cavity is formed between the outer shell 4 and the inner shell 41, the accommodating cavity is filled with a filling material 3. A height difference 31 is formed between the top of the filling material 3 and the top of the outer shell 4, i.e. the top of the filling material is lower than that of the outer shell, and the first heat dissipation loop 51 is configured to be in contact with the filling material 3. The height difference 31 corresponds to the accommodating space.

In this technical solution, the top of the outer shell 4 may be sealed with a detachable end cover to seal the port, preferably but not limited to using methods such as snap-fit, threaded connection, or bolted connection to achieve disassembly. The filling material 3 is typically epoxy resin, and is poured into the accommodating cavity to prevent direct contact between the core assembly 1 and the first heat dissipation loop 51, avoiding short circuits and ensuring the effectiveness of capacitor use. By maintaining the height difference 31 between the filling material and the inner top wall of the outer shell 4, the multiple second heat dissipation channels 501 may be arranged annularly within the height difference 31, contacting both the filling material 3 and the inner top wall of the outer shell 4, and is fixedly connected to the inner shell 41 at the axis of the outer shell 4. With two ends of the inner shell 41 are through ends and penetrating the outer shell 4, allowing the first heat dissipation channels 504 to pass through the inner shell 41 and wrap around the inner wall surface of the inner shell 41, enhancing heat dissipation effect for the core assembly 1. Moreover, the first heat dissipation channels 504 are used to connect the second heat dissipation channels 501 and the third heat dissipation channel 502, improving the connection stability with the housing.

In an embodiment, the core assembly 1 includes:
multiple capacitor cores 11 and a core insulation layer 12, and the capacitor cores 11 are evenly and regularly arranged within the accommodating cavity, and the core insulation layer 12 covers the top of the capacitor cores 11; and a busbar 2 is arranged on one side of the core insulation layer 12 and connected to the capacitor cores 11, and extends out of the housing in a direction away from the capacitor cores 11.

The multiple capacitor cores 11 are arranged regularly, covered by the core insulation layer 12, installed in the accommodating cavity, and covered with the filling layer. The busbar 2 extending out of the housing ensures normal operation of the capacitor cores 11. It is understandable that arranging the multiple first heat dissipation channels 504 inside the inner ring of the inner shell 41 may effectively avoid contact with the busbar 2, avoiding structural short circuits.

The working process of this embodiment is as follows.

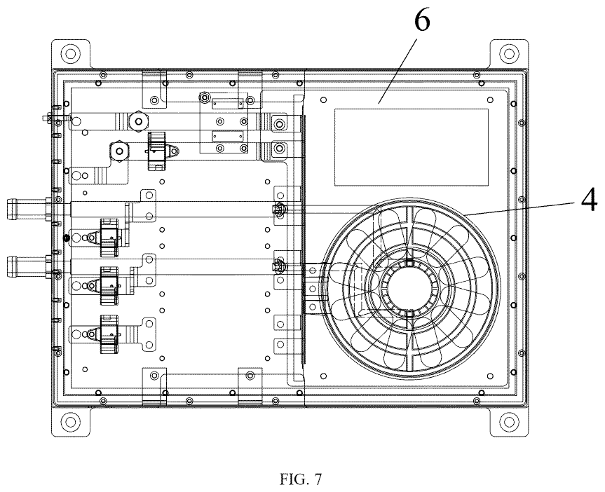

With reference to FIG. 7, the housing is installed in the motor controller 6, and the inlet 505 and outlet 506 formed on the first heat dissipation channels 504 are respectively communicated with the external coolant paths. After the coolant is introduced into the first heat dissipation channels 504 through the inlet 505, the coolant flows into the third heat dissipation channel 502 via the throttling channels 507 while simultaneously entering the second heat dissipation channels 501 along the first heat dissipation channels 504. During this process, the first heat dissipation channels 504, the second heat dissipation channels 501, and third heat dissipation channel 502 simultaneously perform heat dissipation, achieving high-efficiency heat dissipation for the capacitor. The third heat dissipation channel 502 ensures the structural stability of the second heat dissipation channels 501, and the second heat dissipation channels 501 are arranged within the height difference 31 between the filling material 3 and the outer shell 4, achieving efficient heat dissipation while effectively reducing the volume proportion occupied by the heat dissipation device.

In the description of the present disclosure, it should be understood that the terms “longitudinal”, “transverse”, “up”, “down”, “front”, “back”, “left”, “right”, “vertical”, “horizontal”, “top”, “bottom”, “inside”, “outside”, etc. indicate orientation or positional relationships based on the orientation or positional relationships shown in the accompanying drawings, only for the convenience of describing the present disclosure, and do not indicate or imply that the device or element referred to must have a specific orientation, be constructed and operated in a specific orientation, and therefore cannot be understood as a limitation of the present disclosure.

The above-mentioned embodiments only describe the preferred mode of the present disclosure, and do not limit the scope of the present disclosure. Under the premise of not departing from the design spirit of the present disclosure, various modifications and improvements made by one of ordinary skill in the art to the technical solution of the present disclosure should fall within the protection scope determined by the claims of the present disclosure.

What is claimed is:

1. An integrated heat dissipation device for an annular capacitor, comprising:
a housing, wherein an accommodating cavity with an annular structure is formed inside the housing;
a core assembly arranged within the accommodating cavity, wherein an accommodating space is formed between the core assembly and an inner end surface of the housing;
a first heat dissipation loop arranged within the accommodating space, wherein the first heat dissipation loop is filled with a coolant;
a second heat dissipation loop arranged outside the housing, wherein the second heat dissipation loop is configured to cooperate with the first heat dissipation loop to respectively exchange heat with opposite sides of the core assembly; and
a pair of flow distribution mechanisms arranged on the housing, and configured to exchange heat with an inner side of the housing, wherein the pair of flow distribution mechanisms are in communication with the first heat dissipation loop and the second heat dissipation loop, and the pair of flow distribution mechanisms are configured to extend in a direction away from the housing and respectively form an inlet channel and an outlet channel for circulating the coolant;
wherein the first heat dissipation loop and the second heat dissipation loop respectively form circulation paths in at least two different directions from an inlet end to an outlet end through the pair of flow distribution mechanisms.

2. The integrated heat dissipation device for an annular capacitor according to claim 1, wherein the pair of flow distribution mechanisms are configured to form a plurality of circumferentially distributed heat dissipation ends corresponding to a side wall surface of the accommodating cavity, the pair of flow distribution mechanisms are in communication with opposite sides of the first heat dissipation loop and the second heat dissipation loop, one of the pair of flow distribution mechanisms is used to introduce the coolant, and another of the pair of flow distribution mechanisms is used to discharge the coolant.

3. The integrated heat dissipation device for an annular capacitor according to claim 1, wherein the pair of flow distribution mechanisms comprise a plurality of first heat dissipation channels, the first heat dissipation channels are uniformly distributed on an inner wall surface of an inner ring of the accommodating cavity, ends of the first heat dissipation channels extend in a direction away from the housing for introducing and discharging the coolant respectively, other ends of the first heat dissipation channels are in communication with the first heat dissipation loop, throttling channels are integrally formed on the first heat dissipation channels, and the throttling channels are configured to be in communication with the second heat dissipation loop.

4. The integrated heat dissipation device for an annular capacitor according to claim 1, wherein one of the pair of flow distribution mechanisms is configured to cover half of an inner wall surface of an inner ring of the accommodating cavity.

5. The integrated heat dissipation device for an annular capacitor according to claim 3, wherein the first heat dissipation loop comprises a plurality of second heat dissipation channels arranged within the accommodating space, the second heat dissipation channels cooperate to form a multi-layer annular structure about a same center, the center is located on a same axis as a center of the housing, the second heat dissipation channels are in communication with each other through a pair of connecting channels, and the pair of connecting channels are configured to respectively be in communication with the first heat dissipation channels of the pair of flow distribution mechanisms.

6. The integrated heat dissipation device for an annular capacitor according to claim 3, wherein the second heat dissipation loop comprises a third heat dissipation channel arranged on a side, away from the first heat dissipation loop, outside the housing, a groove is provided on a side, close to the housing, of the third heat dissipation channel, the groove cooperates with an outer wall of the housing to form a sealed cavity, and the first heat dissipation channels of the pair of flow distribution mechanisms are respectively in communication with opposite sides of the groove.

7. The integrated heat dissipation device for an annular capacitor according to claim 6, wherein embedded slots are oppositely provided on an inner side wall of the groove, and each of the throttling channels is clamped with a corresponding one of the embedded slots.

8. The integrated heat dissipation device for an annular capacitor according to claim 3, wherein the housing comprises an outer shell and an inner shell fixedly connected to the outer shell, two ends of the inner shell are through ends, the first heat dissipation channels penetrate the inner shell and contact with an inner wall surface of the inner shell, the accommodating cavity is formed between the outer shell and the inner shell, the accommodating cavity is filled with a filling material, a height difference is formed between a top of the filling material and a top of the outer shell, and the first heat dissipation loop is configured to be arranged in the height difference to contact with the filling material.

9. The integrated heat dissipation device for an annular capacitor according to claim 1, wherein the core assembly comprises a plurality of capacitor cores and a core insulation layer, the capacitor cores are regularly arranged within the accommodating cavity, the core insulation layer covers a top of the capacitor cores, a busbar is arranged on one side of the core insulation layer, the busbar is connected to the capacitor cores, and the busbar extends out of the housing in a direction away from the capacitor cores.
